(19) United States
(12) Patent Application Publication
(10) Pub. No.: US 2024/0235490 A1
(43) Pub. Date: Jul. 11, 2024

(54) POWER AMPLIFIER CIRCUIT

(71) Applicant: Murata Manufacturing Co., Ltd., Kyoto (JP)

(72) Inventor: Shohei IMAI, Kyoto (JP)

(21) Appl. No.: 18/405,258

(22) Filed: Jan. 5, 2024

(30) Foreign Application Priority Data
Jan. 5, 2023 (JP) 2023-000582

(51) Int. Cl. H03F 1/02; H03F 1/56; H03F 3/24; H03F 3/60

(52) U.S. Cl. CPC H03F 1/0288; H03F 1/565; H03F 3/245; H03F 3/602; H03F 2200/451

(57) ABSTRACT

A divider circuit divides an input signal into first, second, third, and fourth input signals. A first carrier amplifier amplifies the first input signal and outputs a first output signal. A first peak amplifier amplifies the second input signal and outputs a second output signal. A first converter inputs the first and second output signals. A second carrier amplifier amplifies the third input signal and outputs a third output signal, the first and second carrier amplifiers forming a differential pair. A second peak amplifier amplifies the fourth input signal and outputs a fourth output signal, the first and second peak amplifiers forming a differential pair. A second converter inputs the third output signal and is electrically connected to the first converter. A combiner is electrically connected to an output terminal or a ground and to the first and second converters.

### CROSS REFERENCE TO RELATED APPLICATION

This application claims priority from Japanese Patent Application No. 2023-000582 filed on Jan. 5, 2023. The content of this application is incorporated herein by reference in its entirety.

### BACKGROUND ART

The present disclosure relates to a power amplifier circuit.

In typical Doherty amplifier circuits, a carrier amplifier that operates regardless of the power level of an input signal and a peak amplifier that is turned off when the power level of an input signal is low and turned on when the power level of an input signal is high are connected in parallel. By combining, using a combiner, an output of the carrier amplifier and an output of the peak amplifier, a Doherty amplifier circuit operates as a high-efficiency power amplifier.

A quarter wavelength line used as the combiner is not suitable for reduction in size and increase in bandwidth. Meanwhile, a Doherty amplifier circuit that does not use a quarter wavelength line is disclosed (for example, see Japanese Unexamined Patent Application Publication No. 2021-192476).

### BRIEF SUMMARY

The power amplifier circuit described in Japanese Unexamined Patent Application Publication No. 2021-192476, which has a configuration not including a quarter wavelength line, achieves reduction in size and increase in bandwidth. However, a further increase in bandwidth has been demanded for power amplifier circuits.

Accordingly, it is an object of the present disclosure to provide a power amplifier circuit capable of increasing a bandwidth.

A power amplifier circuit according to an aspect of the present disclosure includes a divider circuit that divides an input signal into a first input signal, a second input signal whose phase is delayed by approximately 90 degrees with respect to a phase of the first input signal, a third input signal whose phase is delayed by approximately 180 degrees with respect to the phase of the first input signal, and a fourth input signal whose phase is delayed by approximately 180 degrees with respect to the phase of the second input signal; a first carrier amplifier that amplifies the first input signal and outputs a first output signal; a first peak amplifier that amplifies the second input signal and outputs a second output signal; a first converter that includes a first transformer including a first inductor and a second inductor, a capacitor connected in parallel with the first inductor, and a capacitor connected in parallel with the second inductor and is configured in such a manner that the first output signal is input to one end of the first inductor and the second output signal is input to one end of the second inductor; a second carrier amplifier that amplifies the third input signal and outputs a third output signal, the first carrier amplifier and the second carrier amplifier forming a differential pair; a second peak amplifier that amplifies the fourth input signal and outputs a fourth output signal, the first peak amplifier and the second peak amplifier forming a differential pair; a second converter that includes a second transformer including a third inductor and a fourth inductor, a capacitor connected in parallel with the third inductor, and a capacitor connected in parallel with the fourth inductor and is configured in such a manner that the third output signal is input to one end of the third inductor, the fourth output signal is input to one end of the fourth inductor, and the other end of the fourth inductor is electrically connected to the other end of the second inductor; and a combiner that includes a third transformer including a fifth inductor and a sixth inductor, a fifth capacitor connected in parallel with the fifth inductor, and a sixth capacitor whose one end is electrically connected to one end of the sixth inductor and other end is electrically connected to an output terminal or a ground and is configured in such a manner that one end of the fifth inductor is electrically connected to the other end of the first inductor and the other end of the fifth inductor is electrically connected to the other end of the third inductor.

A power amplifier circuit according to an aspect of the present disclosure includes a first divider that includes a first transformer including a first inductor and a second inductor, a first capacitor connected in parallel with the first inductor, and a second capacitor connected in parallel with the second inductor and divides a first signal input to one end of the first inductor into a first input signal and a second input signal whose phase is delayed by approximately 90 degrees with respect to a phase of the first input signal; a first carrier amplifier that amplifies the first input signal and outputs a first output signal; a first peak amplifier that amplifies the second input signal and outputs a second output signal; and a combiner circuit that combines the first output signal and the second output signal.

A power amplifier circuit according to an aspect of the present disclosure includes a first divider that includes a first transformer including a first inductor and a second inductor, and a capacitor connected in parallel with the second inductor, an input signal being input, through a capacitor, to one end of the first inductor, and divides the input signal into a first input signal through one end of the second inductor and a second input signal through the other end of the second inductor; a second divider that includes a second transformer including a third inductor and a fourth inductor, one end of the third inductor being electrically connected to the other end of the first inductor, a capacitor connected in parallel with the third inductor, and a capacitor connected in parallel with the fourth inductor and divides the input signal into a third input signal through one end of the fourth inductor and a fourth input signal through the other end of the fourth inductor; a first carrier amplifier that amplifies the first input signal and outputs a first output signal; a second carrier amplifier that amplifies the second input signal and outputs a second output signal, the first carrier amplifier and the second carrier amplifier forming a differential pair; a first peak amplifier that amplifies the third input signal and outputs a third output signal; a second peak amplifier that amplifies the fourth input signal and outputs a fourth output signal, the first peak amplifier and the second peak amplifier forming a differential pair; and a combiner circuit that combines the first output signal, the second output signal, the third output signal, and the fourth output signal.

According to the present disclosure, a power amplifier circuit capable of increasing a bandwidth can be provided.

### BRIEF DESCRIPTION OF THE DRAWINGS

FIG. 1 is a configuration diagram illustrating a schematic configuration of a power amplifier circuit according to a first embodiment;

FIG. 2 is a diagram for explaining an increase in a bandwidth on an output side of the power amplifier circuit;

FIG. 3 is a graph illustrating an example of improvement of a fractional bandwidth in the power amplifier circuit;

FIG. 4 is a diagram illustrating an example of a power amplifier circuit including a divider circuit that can be regarded as a voltage source;

FIG. 5 is a graph illustrating variations in the phase difference between a carrier amplifier and a peak amplifier with respect to an inductor ratio in the divider circuit;

FIG. 6 is a diagram illustrating a modification of the power amplifier circuit according to the first embodiment; and

FIG. 7 is a configuration diagram illustrating a schematic configuration of a power amplifier circuit according to a second embodiment.

### DETAILED DESCRIPTION

Hereinafter, embodiments of the present disclosure will be described with reference to drawings. Circuit elements denoted by the same signs represent the same circuit elements, and repetitive description will be omitted.

### Power Amplifier Circuit 100 According to First Embodiment

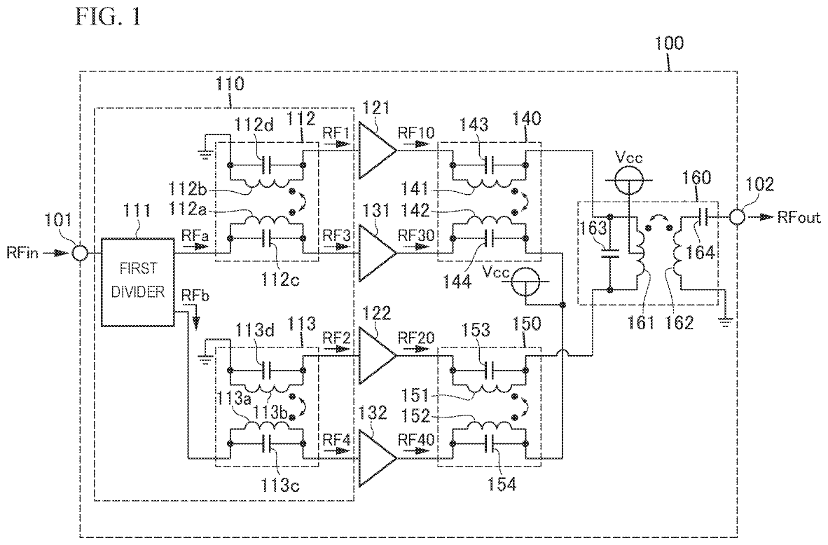

A configuration of a power amplifier circuit 100 according to a first embodiment will be described with reference to FIG. 1. FIG. 1 is a configuration diagram illustrating a schematic configuration of the power amplifier circuit 100 according to the first embodiment.

The power amplifier circuit 100 is mounted on, for example, a mobile phone and is used to amplify power of a signal to be transmitted to a base station. The power amplifier circuit 100 is, for example, mounted on a mobile communication device such as a mobile phone, amplifies power of an input signal RFin to a level required for transmission to the base station, and outputs the amplified input signal RFin as an amplification signal RFout. The input signal RFin is a radio frequency (RF) signal modulated by, for example, a radio frequency integrated circuit (RFIC) in accordance with a predetermined communication method. Communication standards for the input signal RFin include, for example, 2G (the second generation mobile communication system), 3G (the third generation mobile communication system), 4G (the fourth generation mobile communication system), 5G (the fifth generation mobile communication system), LTE (Long Term Evolution)-FDD (Frequency Division Duplex), LTE-TDD (Time Division Duplex), LTE-Advanced, and LTE-Advanced Pro. For example, the input signal RFin has a frequency ranging from approximately several hundreds of MHz to approximately several tens of GHz. The communication standards and frequency of the input signal RFin are not limited to the examples mentioned above.

The power amplifier circuit 100 amplifies the input signal RFin and outputs the output signal RFout. The input signal is an RF signal. The frequency of the input signal is, for example, approximately several GHz.

The power amplifier circuit 100 is a circuit that includes a Doherty amplifier circuit, improves a matching bandwidth on an input side of various amplifiers, and improves frequency characteristics on an output side of the various amplifiers so that a wider bandwidth is achieved.

As illustrated in FIG. 1, the power amplifier circuit 100 includes, for example, an input terminal 101, an output terminal 102, a divider circuit 110, a first carrier amplifier 121, a second carrier amplifier 122, a first peak amplifier 131, a second peak amplifier 132, a first converter 140, a second converter 150, and a combiner 160. The component elements will be described below.

Hereinafter, for convenience of explanation, a side of the first carrier amplifier 121, the second carrier amplifier 122, the first peak amplifier 131, and the second peak amplifier 132 that is near the input terminal 101 will be referred to as an “input side”, and a side of the first carrier amplifier 121, the second carrier amplifier 122, the first peak amplifier 131, and the second peak amplifier 132 that is near the output terminal 102 will be referred to as an “output side”.

For example, the divider circuit 110 divides the input signal RFin, which is input to the divider circuit 110, into an input signal RF1, an input signal RF2, an input signal RF3, and an input signal RF4.

For example, the divider circuit 110 is configured to output the input signal RF1 to the first carrier amplifier 121, output the input signal RF3 to the first peak amplifier 131, output the input signal RF2 to the second carrier amplifier 122, and output the input signal RF4 to the second peak amplifier 132.

The divider circuit 110 includes, for example, a first divider 111, a second divider 112, and a third divider 113.

The first divider 111 outputs an input signal RFa and an input signal RFb whose phase is delayed by approximately 180 degrees with respect to the phase of the input signal RFa. “Approximately 180 degrees” includes, for example, the range from 135 degrees to 225 degrees. The first divider 111 is, for example, a balun transformer.

For example, the second divider 112 divides the input signal RFa into the input signal RF1 and the input signal RF3 whose phase is delayed by 90 degrees with respect to the phase of the input signal RF1. The second divider 112 includes, for example, a transformer including an inductor 112a and an inductor 112b, a capacitor 112c connected in parallel with the inductor 112a, and a capacitor 112d connected in parallel with the inductor 112b.

The transformer may also have an impedance matching function by adjusting the winding ratio of the inductor 112a and the inductor 112b. Thus, the power amplifier circuit 100 is capable of achieving impedance matching by the transformer formed on a chip, without necessarily forming an output matching circuit outside the chip. Therefore, a reduction in the circuit scale can be achieved.

The input signal RFa is input to one end of the inductor 112a, and the other end of the inductor 112a is electrically connected to the first peak amplifier 131, which will be described later. One end of the inductor 112b is electrically connected to a reference potential, and the other end of the inductor 112b is electrically connected to the first carrier amplifier 121, which will be described later.

For example, the capacitor 112c and the capacitor 112d are intended to eliminate the influence of a parasitic inductance of the transformer and are provided for impedance matching of the transformer.

That is, for example, the second divider 112 divides the input signal RFa input to the one end of the inductor 112a into the signal RF1 to be output to the first carrier amplifier 121 and the input signal RF3 to be output to the first peak amplifier 131, the phase of the input signal RF3 being delayed by 90 degrees with respect to the phase of the signal RF1, while achieving impedance matching with a load side.

For example, the third divider 113 divides the input signal RFb into the input signal RF2 and the input signal RF4 whose phase is delayed by 90 degrees with respect to the phase of the input signal RF2. The third divider 113 includes, for example, a transformer including an inductor 113a and an inductor 113b, a capacitor 113c connected in parallel with the inductor 113a, and a capacitor 113d connected in parallel with the inductor 113b.

The input signal RFb is input to one end of the inductor 113a, and the other end of the inductor 113a is electrically connected to the second peak amplifier 132, which will be described later. One end of the inductor 113b is electrically connected to the reference potential, and the other end of the inductor 113b is electrically connected to the second carrier amplifier 122, which will be described later.

For example, the capacitor 113c and the capacitor 113d are intended to eliminate the influence of a parasitic inductance of the transformer and are provided for impedance matching of the transformer.

That is, for example, the third divider 113 divides the input signal RFb input to the one end of the inductor 113a into the input signal RF2 to be output to the second carrier amplifier 122 and the input signal RF4 to be output to the second peak amplifier 132, the phase of the input signal RF4 being delayed by 90 degrees with respect to the phase of the input signal RF2, while achieving impedance matching with the load side.

In the divider circuit 110, the second divider 112 and the third divider 113 each performs division into two signals with a phase difference of 90 degrees. Thus, a quarter wavelength line for achieving operation as a Doherty amplifier circuit is optional, and a reduction in the size of the power amplifier circuit 100 can be achieved.

Furthermore, the divider circuit 110 is capable of increasing the bandwidth by adjusting the phase difference between divided signals. This point will be described in detail below.

The first carrier amplifier 121 amplifies the input signal RF1, which is input to the first carrier amplifier 121, and outputs an output signal RF10. The first carrier amplifier 121 is biased to become, for example, a Class AB amplifier or a Class B amplifier.

The second carrier amplifier 122 amplifies the input signal RF2, which is input to the second carrier amplifier 122, and outputs an output signal RF20. The second carrier amplifier 122 is biased to become, for example, a Class AB amplifier or a Class B amplifier.

The first peak amplifier 131 amplifies the input signal RF3, which is input to the first peak amplifier 131, and outputs an output signal RF30. The first peak amplifier 131 is biased to become, for example, a Class AB amplifier or a Class C amplifier.

The second peak amplifier 132 amplifies the input signal RF4, which is input to the second peak amplifier 132, and outputs an output signal RF40. The second peak amplifier 132 is biased to become, for example, a Class AB amplifier or a Class C amplifier.

That is, the first carrier amplifier 121 and the second carrier amplifier 122 operate when the power level of the input signal RFin is zero or more, regardless of the power level of the input signal RFin. In contrast, the first peak amplifier 131 and the second peak amplifier 132 operate only when the voltage level of the input signal RFin is equal to or more than a level Vback (hereinafter, may also be referred to as “back off”) that is lower than the maximum level V max by a predetermined level.

As described above, the first peak amplifier 131 and the second peak amplifier 132 operate when the power level of the input signal RFin is equal to or more than the value that is lower than the maximum level by the predetermined level (for example, about 6 dB) and is equal to or more than zero.

In the power amplifier circuit 100, by combining two types of amplifiers in accordance with the power level of an input signal, the region in which the first carrier amplifier 121 and the second carrier amplifier 122 operate with saturation output increases. Thus, compared to a power amplifier circuit including only one type of amplifier, the power efficiency increases.

Furthermore, in the power amplifier circuit 100, the first carrier amplifier 121 and the second carrier amplifier 122 form a differential pair, and the first peak amplifier 131 and the second peak amplifier 132 form a differential pair. A differential pair includes a pair of two amplifier elements. The differential pair amplifies a potential difference between signals that are input to the two amplifier elements and have the same amplitude and opposite phase and then performs outputting.

As described above, in the case where signals of the same amplitude and the same phase (for example, noise) are input to the two amplifier elements at the same time, the signals of the same amplitude and same phase are canceled out. That is, by using the differential pair as the first carrier amplifier 121 and the second carrier amplifier 122 and the differential pair as the first peak amplifier 131 and the second peak amplifier 132, generation of noise and harmonic waves of input signals can be suppressed.

Amplifier elements configuring a differential pair are not particularly limited. The amplifier elements may be, for example, bipolar transistors such as heterojunction bipolar transistors (HBTs) or field effect transistors such as metal-oxide-semiconductor field effect transistors (MOSFETs).

The first converter 140 combines the output signal RF10 output from the first carrier amplifier 121 and the output signal RF30 whose phase is delayed by 90 degrees with respect to the phase of the output signal RF10.

The first converter 140 includes a transformer including an inductor 141 and an inductor 142, a capacitor 143 connected in parallel with the inductor 141, and a capacitor 144 connected in parallel with the inductor 142.

The output signal RF10 is input to one end of the inductor 141, and the other end of the inductor 141 is electrically connected to the combiner 160, which will be described later. One end of the inductor 142 is electrically connected to the output of the first peak amplifier 131. Electric power is supplied to the other end of the inductor 142 from a power supply Vcc, and the other end of the inductor 142 is electrically connected to the other end of an inductor 152.

For example, the capacitor 143 and the capacitor 144 are intended to eliminate the influence of a parasitic inductance of the transformer and are provided for impedance matching of the transformer.

The second converter 150 combines the output signal RF20 output from the second carrier amplifier 122 and the output signal RF40 whose phase is delayed by approximately 90 degrees with respect to the phase of the output signal RF20.

The second converter 150 includes a transformer including an inductor 151 and the inductor 152, a capacitor 153 connected in parallel with the inductor 151, and a capacitor 154 connected in parallel with the inductor 152.

The output signal RF20 is input to one end of the inductor 151, and the other end of the inductor 151 is electrically connected to the combiner 160, which will be described later. One end of the inductor 152 is electrically connected to the output of the second peak amplifier 132. Electric power is supplied to the other end of the inductor 152 from the power supply Vcc, and the other end of the inductor 152 is electrically connected to the other end of the inductor 142.

For example, the capacitor 153 and the capacitor 154 are intended to eliminate the influence of a parasitic inductance of the transformer and are provided for impedance matching of the transformer.

The combiner 160 combines signals output from the first converter 140 and the second converter 150 and outputs the output signal RFout.

The combiner 160 includes a transformer including an inductor 161 and an inductor 162, a capacitor 163 connected in parallel with the inductor 161, and a capacitor 164 whose one end is electrically connected to one end of the inductor 161 and other end is electrically connected to the output terminal.

One end of the inductor 161 is electrically connected to the other end of the inductor 141, and the other end of the inductor 161 is electrically connected to the other end of the inductor 151. Electric power is supplied to a midpoint of the inductor 161 from the power supply Vcc. The midpoint includes a point that is equally distant from the one end and the other end of the inductor 161 and a point in the vicinity of the point that is equally distant from the one end and the other end of the inductor 161.

In the power amplifier circuit 100, an increase in the bandwidth can be achieved by the first converter 140, the second converter 150, and the combiner 160. This will be described in a concrete manner.

### Circuit on Output Side

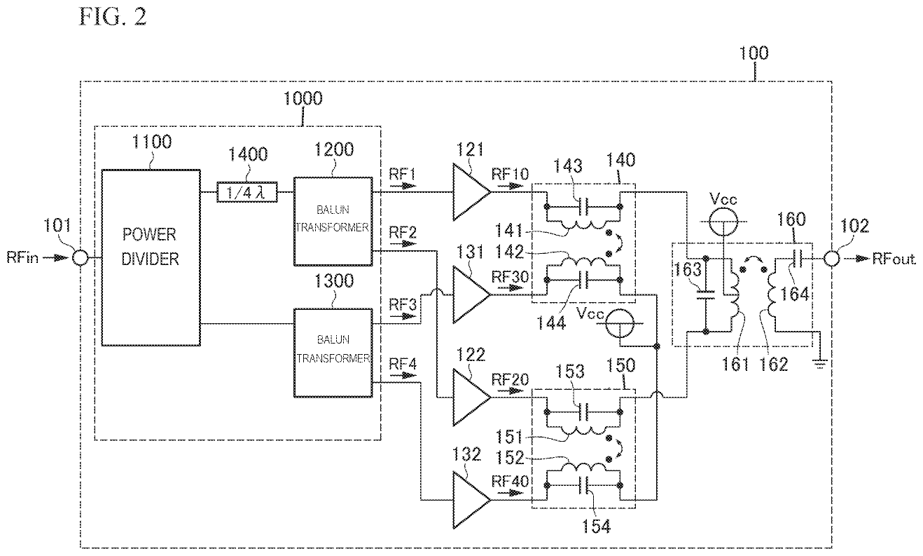

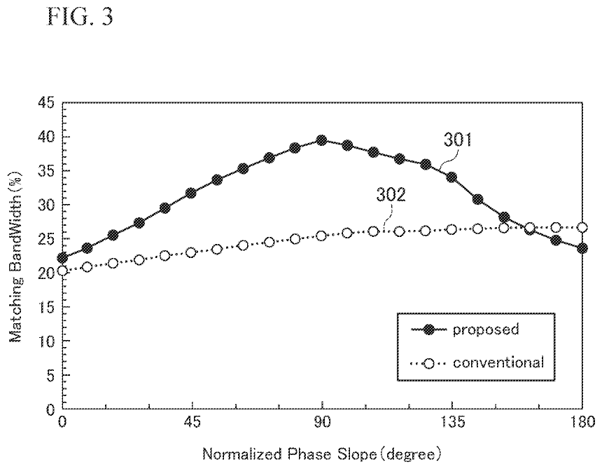

An operation for achieving an increase in the bandwidth on the output side of the power amplifier circuit 100 will be described with reference to FIGS. 2 and 3. FIG. 2 is a diagram for explaining an increase in the bandwidth on the output side of the power amplifier circuit 100. FIG. 3 is a graph illustrating an example of improvement of a fractional bandwidth in the power amplifier circuit 100.

The power amplifier circuit 100 only needs to have a configuration, on the input side thereof, for providing a phase difference of 90 degrees between a signal input to a carrier amplifier and a signal input to a peak amplifier. “90 degrees” includes, for example, the range from 45 degrees to 135 degrees.

Hereinafter, for convenience of explanation of an increase in the bandwidth on the output side of the power amplifier circuit 100, for example, a circuit on the input side of the power amplifier circuit 100 includes a power divider 1100, balun transformers 1200 and 1300 and a quarter wavelength line, as illustrated in FIG. 2. The power divider 1100 maybe, for example, a Wilkinson power divider including quarter wavelength lines connected in parallel and a resistor element electrically connecting one ends of the quarter wavelength lines. With this arrangement, the phase of a signal input to a carrier amplifier is different from the phase of a signal input to a peak amplifier by 90 degrees.

As described above, the first converter 140, the second converter 150, and the combiner 160 are provided on the output side of the power amplifier circuit 100.

In the power amplifier circuit 100 illustrated in FIG. 2, the first converter 140 converts the first peak amplifier 131 into a voltage source, and the second converter 150 converts the second peak amplifier 132 into a voltage source. By connecting the first peak amplifier 131 and the second peak amplifier 132, which have been converted into voltage sources, in series with the first carrier amplifier 121 and the second carrier amplifier 122, a Doherty amplifier circuit is configured.

In the power amplifier circuit 100, outputs from the first carrier amplifier 121 and the second carrier amplifier 122, which form a differential pair, are combined at the combiner 160 that is to be converted into a current source.

As described above, in the power amplifier circuit 100, by combining differential signals at the combiner 160, which is to be converted into a current source, frequency characteristics generated by the first converter 140 and the second converter 150 can be canceled out by the frequency characteristics of the combiner 160. Such canceling out is achieved by the combiner 160 operating in such a manner that the frequency characteristics generated by the first converter 140 and the second converter 150 are canceled out. Thus, the first carrier amplifier 121 and the second carrier amplifier 122 can be caused to operate using a wider bandwidth.

Improvement of a fractional bandwidth in the power amplifier circuit 100 illustrated in FIG. 2 will be described with reference to FIG. 3. In FIG. 3, the vertical axis represents a fractional bandwidth for which impedance matching is achieved, and the horizontal axis represents the phase difference between a carrier amplifier and a peak amplifier. Furthermore, in FIG. 3, for example, the frequency characteristics of the phase difference in the power amplifier circuit 100 including the combiner 160 illustrated in FIG. 2 are denoted by sign “301”, and the frequency characteristics of the phase difference in the power amplifier circuit 100 not including the combiner 160 are denoted by sign “302”.

As illustrated in FIG. 3, the maximum frequency characteristics of the power amplifier circuit 100 not including the combiner 160 are approximately 26% even when the phase difference is changed, and the maximum frequency characteristics of the power amplifier circuit 100 including the combiner 160 reach 39.4% by optimizing the phase difference. That is, with the provision of the combiner 160, the power amplifier circuit 100 is capable of significantly improving the fractional bandwidth for which impedance matching is achieved.

Now, grounds for being able to regard the first converter 140 and the second converter 150 as voltage sources will be described. A dependent matrix for the first converter 140 and the second converter 150 is obtained. In the case where a diagonal component of the dependent matrix is “0”, the first converter 140 and the second converter 150 serve as circuits that perform conversion between voltage and current and perform outputting after constant multiplication. That is, in the case where a current source such as a carrier amplifier is connected to the input side of the first converter 140 and the second converter 150, the first converter 140 and the second converter 150 can be regarded as voltage sources when viewed from the output side of the first converter 140 and the second converter 150.

Meanwhile, the combiner 160 can be regarded as a current source. In the case where a non-diagonal component of a dependent matrix for the combiner 160 is “0”, when a current source such as a carrier amplifier is connected to the input side of the combiner 160, the combiner 160 can be regarded as a current source when the combiner 160 is viewed from the load side.

### Circuit on Input Side

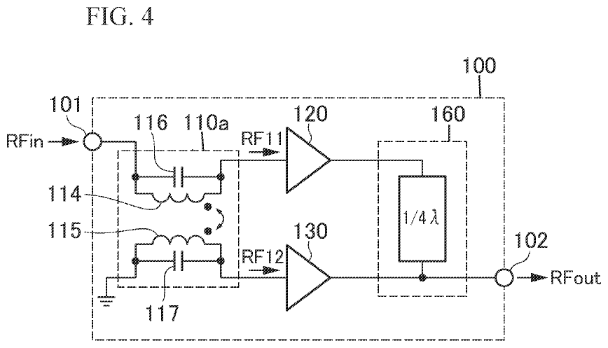

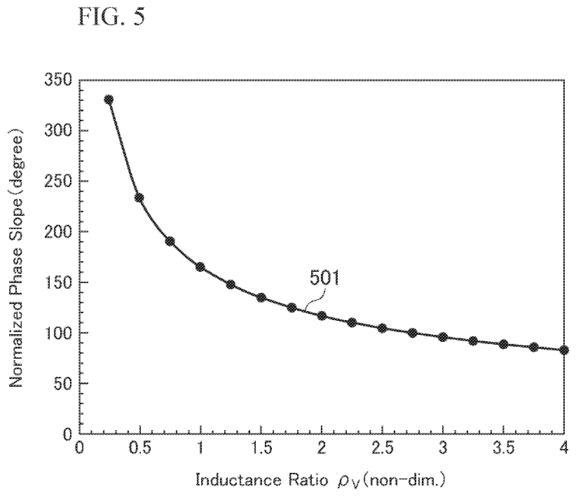

Increasing a bandwidth by setting an optimal phase difference by the divider circuit 110 on the input side of the power amplifier circuit 100 will be described with reference to FIGS. 4 and 5. FIG. 4 is a diagram illustrating an example of the power amplifier circuit 100 including a divider circuit 110a that can be regarded as a voltage source. FIG. 5 is a graph illustrating variations in the phase difference between a carrier amplifier and a peak amplifier with respect to an inductor ratio in the divider circuit 110a.

As described above, the divider circuit 110 including the second divider 112 and the third divider 113 is provided on the input side of the power amplifier circuit 100. Thus, the power amplifier circuit 100 is capable of intentionally setting frequency characteristics for dividing the input signal RFin, without necessarily using a quarter wavelength line.

Hereinafter, for example, as illustrated in FIG. 4, regarding optimization of a phase difference on the input side of the power amplifier circuit 100, for example, the power amplifier circuit 100 includes a single carrier amplifier 120 and a single peak amplifier 130 and also includes the divider circuit 110a.

For example, the divider circuit 110a divides the input signal RFin into an input signal RF11 and an input signal RF12 whose phase is delayed by 90 degrees with respect to the phase of the input signal RF11.

The divider circuit 110a includes, for example, a transformer including an inductor 114 and an inductor 115, a capacitor 116 connected in parallel with the inductor 114, and a capacitor 117 connected in parallel with the inductor 115.

The input signal RFin is input to one end of the inductor 114, and the other end of the inductor 114 is electrically connected to the carrier amplifier 120. One end of the inductor 115 is electrically connected to the reference potential, and the other end of the inductor 115 is electrically connected to the peak amplifier 130.

For example, the capacitor 116 and the capacitor 117 are intended to eliminate the influence of a parasitic inductance of the transformer and are provided for impedance matching of the transformer.

In the power amplifier circuit 100 illustrated in FIG. 4, in the divider circuit 110a, windings of the inductors forming the transformer are adjusted, and the ratio of the two inductances is adjusted.

Adjusting the frequency characteristics of the input signal RF11 and the input signal RF12 by adjusting the ratio of two inductances will be described with reference to FIG. 5. FIG. 5 is a graph illustrating variations in a phase difference with respect to the ratio of two inductances. In FIG. 5, the vertical axis represents a value obtained by normalizing a differentiated phase difference at the designed center frequency, and the horizontal axis represents the ratio of the two inductances.

As illustrated in FIG. 5, the divider circuit 110a exhibits characteristics of a curved line indicated by sign 501. Thus, the divider circuit 110a is capable of adjusting the frequency characteristics of the phase difference by adjusting the ratio of inductances of the inductors. As described above, with the configuration capable of adjusting the frequency characteristics of the phase difference, frequency characteristics of the phase difference that achieves the maximum fractional bandwidth illustrated in FIG. 3 (for example, the phase difference of 90 degrees in FIG. 3) can be set. Thus, an increase in the bandwidth of the power amplifier circuit 100 can be achieved.

As described above, also in the power amplifier circuit 100 illustrated in FIG. 1, the phase difference can be adjusted in a similar manner by adjustment of the winding ratio of inductors configuring the second divider 112 and the third divider 113 included in the divider circuit 110. Thus, the phase difference that achieves the maximum fractional bandwidth illustrated in FIG. 3 can be set.

The transformer in the divider circuit 110a may also have an impedance matching function by adjusting the winding ratio of the inductor 114 and the inductor 115. Thus, the power amplifier circuit 100 is capable of achieving impedance matching using the transformer formed on a chip, without necessarily forming an output matching circuit outside the chip. Therefore, a reduction in the circuit scale can be achieved.

### Modification

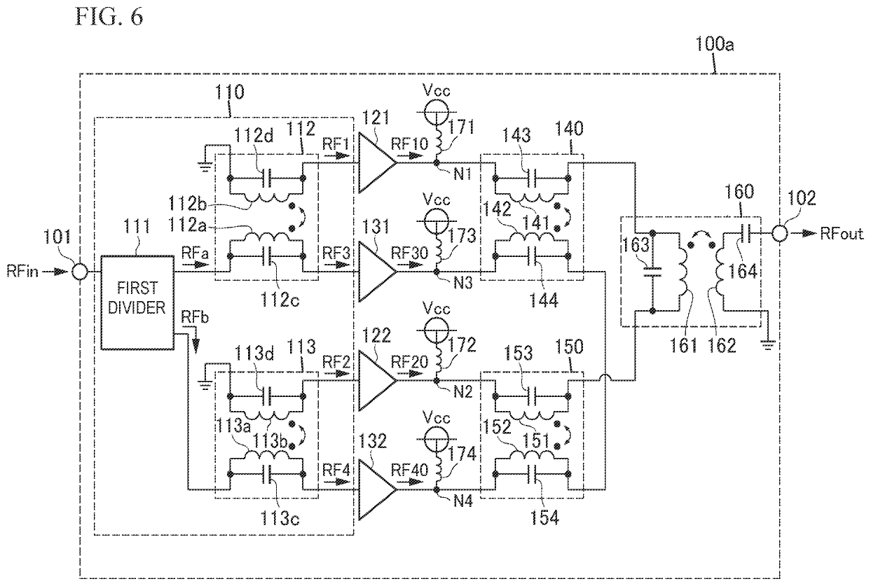

A modification of the power amplifier circuit 100 will be described with reference to FIG. 6. FIG. 6 is a diagram illustrating a modification of the power amplifier circuit 100 according to the first embodiment.

As illustrated in FIG. 6, a power amplifier circuit 100a according to this modification is configured to supply electric power through inductors to the first carrier amplifier 121, the second carrier amplifier 122, the first peak amplifier 131, and the second peak amplifier 132, unlike the power amplifier circuit 100.

Specifically, the power Vcc is supplied through an inductor 171 to a node N1 between the first carrier amplifier 121 and the one end of the inductor 141 of the first converter 140.

Furthermore, the power Vcc is supplied through an inductor 173 to a node N3 between the first peak amplifier 131 and the one end of the inductor 142 of the first converter 140.

Furthermore, the power Vcc is supplied through an inductor 172 to a node N2 between the second carrier amplifier 122 and the one end of the inductor 151 of the second converter 150.

The power Vcc is supplied through an inductor 174 to a node N4 between the second peak amplifier 132 and the one end of the inductor 152 of the second converter 150.

In the power amplifier circuit 100, if the input signal RFin has a high frequency, an operation failure may occur in the combiner 160 due to a parasitic capacitance generated at each amplifier.

Thus, in the power amplifier circuit 100a, electric power is supplied through an inductor to each amplifier, so that parallel resonance between the output parasitic capacitance generated at the amplifier and the inductor can be achieved. Accordingly, in the power amplifier circuit 100a, attenuation of a signal caused by a current flowing to a parasitic capacitance at a high frequency can be suppressed, and the maximum performance of the combiner 160 can thus be exhibited.

### Power Amplifier Circuit 200 According to Second Embodiment

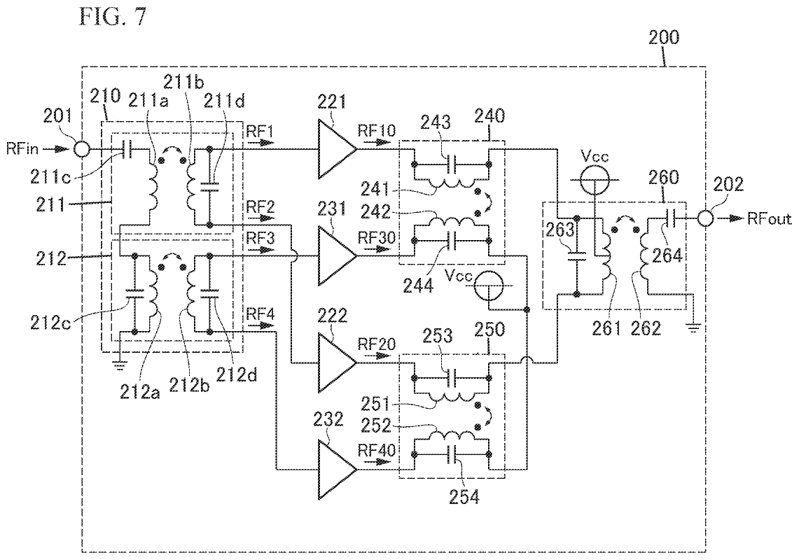

A power amplifier circuit 200 according to a second embodiment will be described with reference to FIG. 7. FIG. 7 is a configuration diagram illustrating a schematic configuration of the power amplifier circuit 200 according to the second embodiment. Description of features of the power amplifier circuit 200 according to the second embodiment that are common to the embodiment described above will be omitted, and only different points will be described. In particular, similar operational effects achieved by similar configurations will not be repeatedly described.

As illustrated in FIG. 7, the power amplifier circuit 200 is different from the power amplifier circuit 100 according to the first embodiment in the configuration of a circuit on the input side.

Specifically, a divider circuit 210 includes a divider (hereinafter, referred to as a “current source divider 211”) that can be regarded as a current source and a divider (hereinafter, referred to as a “voltage source divider 212”) that can be regarded as a voltage source.

The current source divider 211 includes, for example, a transformer including an inductor 211a and an inductor 211b and a capacitor 211d connected in parallel with the inductor 211b.

The input signal RFin is input, through a capacitor 211c, to one end of the inductor 211a. Then, the input signal RFin is divided into the input signal RF1 that is to be output from one end of the inductor 211b and the input signal RF2 that is to be output from the other end of the inductor 211b.

The input signal RF1 is input to a first carrier amplifier 221. The input signal RF2 is input to a second carrier amplifier 222.

The voltage source divider 212 includes, for example, a transformer including an inductor 212a and an inductor 212b, a capacitor 212c connected in parallel with the inductor 212a, and a capacitor 212d connected in parallel with the inductor 212b.

One end of the inductor 212a is electrically connected to the other end of the inductor 211a. That is, the input signal RFin is input, through the inductor 211a, to the inductor 212a. Then, the input signal RFin is divided into the input signal RF3 that is to be output from one end of the inductor 212b and the input signal RF4 that is to be output from the other end of the inductor 212b.

The input signal RF3 is input to a first peak amplifier 231. The input signal RF4 is input to a second peak amplifier 232.

In the power amplifier circuit 200, in the case where a non-diagonal component of a dependent matrix for the current source divider 211 is “0”, the current source divider 211 can be regarded as a current source when the current source divider 211 is viewed from the output side.

Furthermore, in the power amplifier circuit 200, in the case where a diagonal component of a dependent matrix for the voltage source divider 212 is “0”, the voltage source divider 212 serves as a circuit that performs conversion between voltage and current and performs outputting after constant multiplication. That is, in the power amplifier circuit 200, the voltage source divider 212 can be regarded as a voltage source when the voltage source divider 212 is viewed from the output side.

Unlike the power amplifier circuit 100 in which the circuit on the input side includes three dividers: the first divider 111 to the third divider 113, the power amplifier circuit 200 can be arranged to include the current source divider 211 and the voltage source divider 212. Thus, size reduction in the power amplifier circuit 200 can be achieved. This arrangement can be implemented because the phase relationship between input terminals (near an input terminal 201) and output terminals (near an output terminal 202) of the current source divider 211 and the voltage source divider 212 is clear.

Specifically, in the power amplifier circuit 100, in the case where a balun transformer is used as the first divider 111, to provide a phase difference of approximately 90 degrees between signals to be input to a carrier amplifier and a peak amplifier, which form a differential pair, the second divider 112 and the third divider 113 need to be provided in the power amplifier circuit 100.

Meanwhile, in the power amplifier circuit 200, when a current flows to the input side of the current source divider 211, a current whose phase is the same as the phase of the current flowing to the input side of the current source divider 211 is generated on the output side. That is, a signal with the same phase and a signal whose phase is different from the phase of the signal with the same phase by approximately 180 degrees are generated on the output side of the current source divider 211. Thus, the input signal RF1 is the signal whose phase is the same as the phase of the input signal RFin, and the input signal RF2 is a signal whose phase is delayed by approximately 180 degrees with respect to the phase of the input signal RFin.

In contrast, when a current flows to the input side of the voltage source divider 212, a current whose phase is different from the phase of the current flowing to the input side of the voltage source divider 212 by approximately 90 degrees is generated on the output side. That is, a signal whose phase is different by approximately 90 degrees and a signal whose phase is different from the signal whose phase is different by approximately 90 degrees by approximately 180 degrees are generated. Thus, the third input signal RF3 is a signal whose phase is delayed by approximately 90 degrees with respect to the phase of the input signal RFin, and the input signal RF4 is a signal whose phase is delayed by approximately 270 degrees with respect to the phase of the input signal RFin. Phase displacement by approximately 90 degrees at the voltage source divider 212 is clear from the fact that a non-diagonal component is provided with “j” indicating an imaginary unit and a diagonal component is not provided with “j” indicating an imaginary unit in a dependent matrix for the voltage source divider 212.

Thus, an increase in the bandwidth can be achieved in the power amplifier circuit 200 that is configured to be capable of setting a phase difference (for example, a phase difference of approximately 90 degrees in FIG. 3) that achieves the maximum fractional bandwidth illustrated in FIG. 3, while the size of a circuit in the power amplifier circuit 200 being reduced.

In FIG. 7, a circuit on the output side of the power amplifier circuit 200 that is arranged to include a first converter 240, a second converter 250, and a combiner 260 is illustrated. However, the arrangement of the circuit on the output side is not limited to the example illustrated in FIG. 7. The circuit on the output side only needs to be a circuit capable of combining signals output from the first carrier amplifier 221, the second carrier amplifier 222, the first peak amplifier 231, and the second peak amplifier 232. For example, the circuit on the output side may be arranged to include the combination of a quarter wavelength line and a balun transformer.

### Summary

<1>

According to an illustrative embodiment of the present disclosure, a power amplifier circuit 100 includes a divider circuit 110 that divides an input signal RFin into an input signal RF1 (first input signal), an input signal RF3 (second input signal) whose phase is delayed by 90 degrees with respect to a phase of the input signal RF1 (first input signal), an input signal RF2 (third input signal) whose phase is delayed by 180 degrees with respect to the phase of the input signal RF1 (first input signal), and an input signal RF4 (fourth input signal) whose phase is delayed by 180 degrees with respect to the phase of the input signal RF3 (second input signal); a first carrier amplifier 121 that amplifies the input signal RF1 (first input signal) and outputs an output signal RF10 (first output signal); a first peak amplifier 131 that amplifies the input signal RF3 (second input signal) and outputs an output signal RF30 (second output signal); a first converter 140 that includes a transformer (first transformer) including an inductor 141 (first inductor) and an inductor 142 (second inductor), a capacitor 143 connected in parallel with the inductor 141 (first inductor), and a capacitor 144 connected in parallel with the inductor 142 (second inductor) and is configured in such a manner that the output signal RF10 (first output signal) is input to one end of the inductor 141 (first inductor) and the output signal RF30 (second output signal) is input to one end of the inductor 142 (second inductor); a second carrier amplifier 122 that amplifies the input signal RF2 (third input signal) and outputs an output signal RF20 (third output signal), the first carrier amplifier 121 and the second carrier amplifier 122 forming a differential pair; a second peak amplifier 132 that amplifies the input signal RF4 (fourth input signal) and outputs an output signal RF40 (fourth output signal), the first peak amplifier 131 and the second peak amplifier 132 forming a differential pair; a second converter 150 that includes a transformer (second transformer) including an inductor 151 (third inductor) and an inductor 152 (fourth inductor), a capacitor 153 connected in parallel with the inductor 151 (third inductor), and a capacitor 154 connected in parallel with the inductor 152 (fourth inductor) and is configured in such a manner that the output signal RF20 (third output signal) is input to one end of the inductor 151 (third inductor), the output signal RF40 (fourth output signal) is input to one end of the inductor 152 (fourth inductor), and the other end of the inductor 152 (fourth inductor) is electrically connected to the other end of the inductor 142; and a combiner 160 that includes a transformer (third transformer) including an inductor 161 (fifth inductor) and an inductor 162 (sixth inductor), a capacitor 163 (fifth capacitor) connected in parallel with the inductor 161 (fifth inductor), and a capacitor 164 (sixth capacitor) whose one end is electrically connected to one end of the inductor 162 (sixth inductor) and other end is electrically connected to an output terminal 102 or a ground and is configured in such a manner that one end of the inductor 161 (fifth inductor) is electrically connected to the other end of the inductor 141 (first inductor) and the other end of the inductor 161 (fifth inductor) is electrically connected to the other end of the inductor 151 (third inductor). Accordingly, the power amplifier circuit 100 can be arranged to include a Doherty amplifier circuit, without necessarily using a quarter wavelength line. Thus, a reduction in the size and an increase in the bandwidth can be achieved.

<2>

According to an illustrative embodiment of the present disclosure, in a power amplifier circuit 100a (modification), a power Vcc is supplied, through an inductor 171, to a node N1 between the first carrier amplifier 121 and the one end of the inductor 141 (first inductor) of the first converter 140, the power Vcc is supplied, through an inductor 173, to a node N3 between the first peak amplifier 131 and the one end of the inductor 142 (second inductor) of the first converter 140, the power Vcc is supplied, through an inductor 172, to a node N2 between the second carrier amplifier 122 and the one end of the inductor 151 (third inductor) of the second converter 150, and the power Vcc is supplied, through an inductor 174, to a node N4 between the second peak amplifier 132 and the one end of the inductor 152 (fourth inductor) of the second converter 150. Accordingly, in the power amplifier circuit 100a, attenuation of a signal caused by a current flowing to a parasitic capacitance at a high frequency can be suppressed. Thus, the maximum performance of the combiner 160 can be exhibited.

<3>

According to an illustrative embodiment of the present disclosure, in the power amplifier circuit 100 according to <1> or <2>, the divider circuit 110 includes a first divider 111 that divides the input signal RFin into an input signal RFa (first signal) and an input signal RFb (second signal) whose phase is delayed by 180 degrees with respect to a phase of the input signal RFa (first signal), a second divider 112 that includes a transformer (fourth transformer) including an inductor 112a (seventh inductor) and an inductor 112b (eighth inductor), a capacitor 112c connected in parallel with the inductor 112a (seventh inductor), and a capacitor 112d connected in parallel with the inductor 112b (eighth inductor) and divides the input signal RFa (first signal) input to one end of the inductor 112a (seventh inductor) into the input signal RF1 (first input signal) to be output through the inductor 112a (seventh inductor) and the input signal RF3 (second input signal) to be output through the inductor 112b (eighth inductor), and a third divider 113 that includes a transformer (fifth transformer) including an inductor 113a (ninth inductor) and an inductor 113b (tenth inductor), a capacitor 113c connected in parallel with the inductor 113a (ninth inductor), and a capacitor 113d connected in parallel with the inductor 113b (tenth inductor) and divides the input signal RFb (second signal) input to one end of the inductor 113a (ninth inductor) into the input signal RF2 (third input signal) to be output through the inductor 113a (ninth inductor) and the input signal RF4 (fourth input signal) to be output through the inductor 113b (tenth inductor). Accordingly, since the power amplifier circuit 100 includes the divider circuit 110 capable of adjusting a phase difference, the phase difference that achieves the maximum fractional bandwidth illustrated in FIG. 3 can be set. Thus, an increase in the bandwidth can be achieved.

<4>

According to an illustrative embodiment of the present disclosure, in a power amplifier circuit 200 according to <1> or <2>, a divider circuit 210 includes a current source divider 211 (fourth divider) that includes a transformer (sixth transformer) including an inductor 211a (eleventh inductor) and an inductor 211b (twelfth inductor), and a capacitor 211d connected in parallel with the inductor 211b (twelfth inductor), the input signal RFin being input, through a capacitor 211c, to one end of the inductor 211a (eleventh inductor), and divides the input signal RFin into the input signal RF1 through one end of the inductor 211b (twelfth inductor) and the input signal RF2 (third input signal) through the other end of the inductor 211b (twelfth inductor), and a voltage source divider 212 (fifth divider) that includes a transformer (seventh transformer) including an inductor 212a (thirteenth inductor) whose one end is electrically connected to the other end of the inductor 211a (eleventh inductor) and an inductor 212b (fourteenth inductor), a capacitor 212c connected in parallel with the inductor 212a (thirteenth inductor), and a capacitor 212d connected in parallel with the inductor 212b (fourteenth inductor) and divides the input signal RFin input through the inductor 211a (eleventh inductor) into the input signal RF3 (second input signal) through one end of the inductor 212b (fourteenth inductor) and the input signal RF4 (fourth input signal) through the other end of the inductor 212b (fourteenth inductor). Accordingly, the power amplifier circuit 200 is capable of setting a phase difference that achieves the maximum fractional bandwidth illustrated in FIG. 3, and an increase in the bandwidth can be achieved, while the size of a circuit being reduced without necessarily using a quarter wavelength line.

<5>

According to an illustrative embodiment of the present disclosure, a power amplifier circuit 100 includes a divider circuit 110a (first divider) that includes a transformer (first transformer) including an inductor 114 (first inductor) and an inductor 115 (second inductor), a capacitor 116 (first capacitor) connected in parallel with the inductor 114 (first inductor), and a capacitor 117 (second capacitor) connected in parallel with the inductor 115 (second inductor) and divides an input signal RFin (first signal) input to one end of the inductor 114 (first inductor) into an input signal RF11 (first input signal) and an input signal RF12 (second input signal) whose phase is delayed by 90 degrees with respect to a phase of the input signal RF11 (first input signal); a carrier amplifier 120 (first carrier amplifier) that amplifies the input signal RF11 (first input signal) and outputs a first output signal; a peak amplifier 130 (first peak amplifier) that amplifies the input signal RF12 (second input signal) and outputs a second output signal; and a combiner 160 that combines the first output signal and the second output signal. Accordingly, since a circuit on an input side of the power amplifier circuit 100 can be arranged without necessarily including a quarter wavelength line, the size of the power amplifier circuit 100 can be reduced. Furthermore, since the power amplifier circuit 100 is capable of setting a phase difference that achieves the maximum fractional bandwidth of a circuit, an increase in the bandwidth can be achieved.

<6>

According to an illustrative embodiment of the present disclosure, in the case where the divider circuit 110a in <5> is the second divider 112 illustrated in FIG. 1, the carrier amplifier 120 is the first carrier amplifier 121, and the peak amplifier 130 is the first peak amplifier 131, the power amplifier circuit 100 further includes a first divider 111 (second divider) that divides the input signal RFin into an input signal RFa (first signal) and an input signal RFb (second signal) whose phase is delayed by 180 degrees with respect to a phase of the input signal RFa (first signal); a third divider 113 that includes a transformer (second transformer) including an inductor 113a (third inductor) and an inductor 113b (fourth inductor), a capacitor 113c connected in parallel with the inductor 113a (third inductor), and a capacitor 113d connected in parallel with the inductor 113b (fourth inductor) and divides the input signal RFb (second signal) input to one end of the inductor 113a (third inductor) into an input signal RF2 (third input signal) and an input signal RF4 (fourth input signal) whose phase is delayed by 90 degrees with respect to a phase of the input signal RF2 (third input signal); a second carrier amplifier 122 that amplifies the input signal RF2 (third input signal) and outputs an output signal RF20 (third output signal), the first carrier amplifier 121 and the second carrier amplifier 122 forming a differential pair; and a second peak amplifier 132 that amplifies an input signal RF4 (fourth input signal) and outputs an output signal RF40 (fourth output signal), the first peak amplifier 131 and the second peak amplifier 132 forming a differential pair. A first converter 140, a second converter 150, and the combiner 160 (combiner) combine the output signal RF10 (first output signal), the output signal RF30 (second output signal), the output signal RF20 (third output signal), and the output signal RF40 (fourth output signal). Accordingly, in the power amplifier circuit 100, a circuit on an input side can be arranged without necessarily including a quarter wavelength line, and the size of the power amplifier circuit 100 can be reduced. Furthermore, the power amplifier circuit 100 is capable of setting a phase difference that achieves the maximum fractional bandwidth of a circuit, and an increase in the bandwidth can be achieved.

<7>

According to an illustrative embodiment of the present disclosure, a power amplifier circuit 200 includes a current source divider 211 (first divider) that includes a transformer (first transformer) including an inductor 211a (first inductor) and an inductor 211b (second inductor), and a capacitor 211d connected in parallel with the inductor 211b (second inductor), an input signal RFin being input, through a capacitor 211c, to one end of the inductor 211a (first inductor), and divides an input signal RFin into an input signal RF1 (first input signal) through one end of the inductor 211b (second inductor) and an input signal RF2 (second input signal) through the other end of the inductor 211b (second inductor); a voltage source divider 212 (second divider) that includes a transformer (second transformer) including an inductor 212a (third inductor) whose one end is electrically connected to the other end of the inductor 211a (first inductor) and an inductor 212b (fourth inductor), a capacitor 212c connected in parallel with the inductor 212a (third inductor), and a capacitor 212d connected in parallel with the inductor 212b (fourth inductor) and divides the input signal RFin into an input signal RF3 (third input signal) through one end of the inductor 212b (fourth inductor) and an input signal RF4 (fourth input signal) through the other end of the inductor 212b (fourth inductor); a first carrier amplifier 221 that amplifies the input signal RF1 (first input signal) and outputs an output signal RF10 (first output signal); a second carrier amplifier 222 that amplifies the input signal RF2 (second input signal) and outputs an output signal RF20 (second output signal), the first carrier amplifier 221 and the second carrier amplifier 222 forming a differential pair; a first peak amplifier 231 that amplifies the input signal RF3 (third input signal) and outputs an output signal RF30 (third output signal); a second peak amplifier 232 that amplifies the input signal RF4 (fourth input signal) and outputs an output signal RF40 (fourth output signal), the first peak amplifier 231 and the second peak amplifier 232 forming a differential pair; and a first converter 240, a second converter 250, and a combiner 260 (combiner circuit) that combine the output signal RF10 (first output signal), the output signal RF20 (second output signal), the output signal RF30 (third output signal), and the output signal RF40 (fourth output signal). Accordingly, the power amplifier circuit 200 is capable of setting a phase difference that achieves the maximum fractional bandwidth illustrated in FIG. 3, and an increase in the bandwidth can be achieved, while the size of a circuit being reduced.

The embodiments described above are provided for facilitating the understanding of the present disclosure and are not to be construed as limiting the present disclosure. Changes or improvements may be made to the present disclosure without necessarily departing from the spirit of the present disclosure, and equivalents thereof are also encompassed in the present disclosure. That is, design changes made to embodiments in an appropriate manner by those skilled in the art are encompassed in the scope of the present disclosure as long as having features of the present disclosure. Elements provided in embodiments and arrangements of the elements are not limited to those illustrated above but may be changed appropriately.

What is claimed is:

1. A power amplifier circuit comprising:
a divider circuit configured to divide an input signal into a first input signal, into a second input signal whose phase is delayed by 90 degrees with respect to a phase of the first input signal, into a third input signal whose phase is delayed by 180 degrees with respect to the phase of the first input signal, and into a fourth input signal whose phase is delayed by approximately 180 degrees with respect to the phase of the second input signal;
a first carrier amplifier configured to amplify the first input signal and to output a first output signal;
a first peak amplifier configured to amplify the second input signal and to output a second output signal;
a first converter that comprises a first transformer comprising a first inductor and a second inductor, a capacitor connected in parallel with the first inductor, and a capacitor connected in parallel with the second inductor, the first output signal being input to a first end of the first inductor and the second output signal being input to a first end of the second inductor;
a second carrier amplifier configured to amplify the third input signal and to output a third output signal, the first carrier amplifier and the second carrier amplifier forming a differential pair;
a second peak amplifier configured to amplify the fourth input signal and to output a fourth output signal, the first peak amplifier and the second peak amplifier forming a differential pair;
a second converter that comprises a second transformer comprising a third inductor and a fourth inductor, a capacitor connected in parallel with the third inductor, and a capacitor connected in parallel with the fourth inductor, the third output signal being input to a first end of the third inductor, the fourth output signal being input to a first end of the fourth inductor, and a second end of the fourth inductor being electrically connected to a second end of the second inductor; and
a combiner that comprises a third transformer comprising a fifth inductor and a sixth inductor, a fifth capacitor connected in parallel with the fifth inductor, and a sixth capacitor having a first end electrically connected to a first end of the sixth inductor and a second being end electrically connected to an output terminal or to ground, the fifth inductor being electrically connected to the second end of the first inductor and a second end of the fifth inductor being electrically connected to a second end of the third inductor.

2. The power amplifier circuit according to claim 1,
wherein power is supplied, through an inductor, to a first node between the first carrier amplifier and the first end of the first inductor of the first converter,
wherein the power is supplied, through an inductor, to a second node between the first peak amplifier and the first end of the second inductor of the first converter,
wherein the power is supplied, through an inductor, to a third node between the second carrier amplifier and the first end of the third inductor of the second converter, and
wherein the power is supplied, through an inductor, to a fourth node between the second peak amplifier and the first end of the fourth inductor of the second converter.

3. The power amplifier circuit according to claim 1, wherein the divider circuit comprises:
a first divider configured to divide the input signal into a first signal and a second signal whose phase is delayed by approximately 180 degrees with respect to a phase of the first signal,
a second divider that comprises a fourth transformer comprising a seventh inductor and an eighth inductor, a capacitor connected in parallel with the seventh inductor, and a capacitor connected in parallel with the eighth inductor, and that is configured to divide the first signal input to a first end of the seventh inductor into the first input signal output through the seventh inductor and into the second input signal output through the eighth inductor, and
a third divider that comprises a fifth transformer comprising a ninth inductor and a tenth inductor, a capacitor connected in parallel with the ninth inductor, and a capacitor connected in parallel with the tenth inductor, and that is configured to divide the second signal input to a first end of the ninth inductor into the third input signal output through the ninth inductor and into the fourth input signal output through the tenth inductor.

4. The power amplifier circuit according to claim 2, wherein the divider circuit comprises:
a first divider configured to divide the input signal into a first signal and a second signal whose phase is delayed by approximately 180 degrees with respect to a phase of the first signal,
a second divider that comprises a fourth transformer comprising a seventh inductor and an eighth inductor, a capacitor connected in parallel with the seventh inductor, and a capacitor connected in parallel with the eighth inductor, and that is configured to divide the first signal input to a first end of the seventh inductor into the first input signal output through the seventh inductor and into the second input signal output through the eighth inductor, and
a third divider that comprises a fifth transformer comprising a ninth inductor and a tenth inductor, a capacitor connected in parallel with the ninth inductor, and a capacitor connected in parallel with the tenth inductor, and that is configured to divide the second signal input to a first end of the ninth inductor into the third input signal output through the ninth inductor and into the fourth input signal output through the tenth inductor.

5. The power amplifier circuit according to claim 1, wherein the divider circuit comprises:
a fourth divider that comprises a sixth transformer comprising an eleventh inductor and a twelfth inductor, and a capacitor connected in parallel with the twelfth inductor, the input signal being input, through a capacitor, to a first end of the eleventh inductor, and that is configured to divide the input signal into the first input signal through a first end of the twelfth inductor and into the third input signal through a second end of the twelfth inductor, and
a fifth divider that comprises a seventh transformer comprising a thirteenth inductor having a first end electrically connected to the second end of the eleventh inductor and a fourteenth inductor, a capacitor connected in parallel with the thirteenth inductor, and a capacitor connected in parallel with the fourteenth inductor, and that is configured to divide the input signal input through the eleventh inductor into the second input signal through a first end of the fourteenth inductor and into the fourth input signal through a second end of the fourteenth inductor.

6. The power amplifier circuit according to claim 2, wherein the divider circuit comprises:
a fourth divider that comprises a sixth transformer comprising an eleventh inductor and a twelfth inductor, and a capacitor connected in parallel with the twelfth inductor, the input signal being input, through a capacitor, to a first end of the eleventh inductor, and that is configured to divide the input signal into the first input signal through a first end of the twelfth inductor and into the third input signal through a second end of the twelfth inductor, and
a fifth divider that comprises a seventh transformer comprising a thirteenth inductor having a first end electrically connected to the second end of the eleventh inductor and a fourteenth inductor, a capacitor connected in parallel with the thirteenth inductor, and a capacitor connected in parallel with the fourteenth inductor, and that is configured to divide the input signal input through the eleventh inductor into the second input signal through a first end of the fourteenth inductor and into the fourth input signal through a second end of the fourteenth inductor.

7. A power amplifier circuit comprising:
a first divider that comprises a first transformer comprising a first inductor and a second inductor, a first capacitor connected in parallel with the first inductor, and a second capacitor connected in parallel with the second inductor, and that is configured to divide a first signal input to a first end of the first inductor into a first input signal and into a second input signal whose phase is delayed by 90 degrees with respect to a phase of the first input signal;
a first carrier amplifier configured to amplify the first input signal and to output a first output signal;
a first peak amplifier configured to amplify the second input signal and to output a second output signal; and
a combiner circuit configured to combine the first output signal and the second output signal.

8. The power amplifier circuit according to claim 7, further comprising:
a second divider configured to divide an input signal into the first signal and a second signal whose phase is delayed by approximately 180 degrees with respect to a phase of the first signal;
a third divider that comprises a second transformer comprising a third inductor and a fourth inductor, a capacitor connected in parallel with the third inductor, and a capacitor connected in parallel with the fourth inductor, and that is configured to divide the second signal input to a first end of the third inductor into a third input signal and into a fourth input signal whose phase is delayed by 90 degrees with respect to a phase of the third input signal;
a second carrier amplifier configured to amplify the third input signal and to output a third output signal, the first carrier amplifier and the second carrier amplifier forming a differential pair; and
a second peak amplifier configured to amplify the fourth input signal and to output a fourth output signal, the first peak amplifier and the second peak amplifier forming a differential pair,
wherein the combiner circuit is configured to combine the first output signal, the second output signal, the third output signal, and the fourth output signal.

9. A power amplifier circuit comprising:
a first divider that comprises a first transformer comprising a first inductor and a second inductor, and a capacitor connected in parallel with the second inductor, an input signal being input, through a capacitor, to a first end of the first inductor, and that is configured to divide the input signal into a first input signal through a first end of the second inductor and into a second input signal through a second end of the second inductor;
a second divider that comprises a second transformer comprising a third inductor having a first end electrically connected to a second end of the first inductor and a fourth inductor, a capacitor connected in parallel with the third inductor, and a capacitor connected in parallel with the fourth inductor, and that is configured to divide the input signal into a third input signal through a first end of the fourth inductor and into a fourth input signal through a second end of the fourth inductor;
a first carrier amplifier configured to amplify the first input signal and to output a first output signal;
a second carrier amplifier configured to amplify the second input signal and to output a second output signal, the first carrier amplifier and the second carrier amplifier forming a differential pair;
a first peak amplifier configured to amplify the third input signal and to output a third output signal;
a second peak amplifier configured to amplify the fourth input signal and to output a fourth output signal, the first peak amplifier and the second peak amplifier forming a differential pair; and
a combiner circuit configured to combine the first output signal, the second output signal, the third output signal, and the fourth output signal.
